(19) United States
(12) Patent Application Publication
(10) Pub. No.: US 2013/0182235 A1
(43) Pub. Date: Jul. 18, 2013

(54) MEASUREMENT SYSTEM THAT INCLUDES AN ENCODER AND AN INTERFEROMETER

(71) Applicant: Nikon Coporation, Tokyo (JP)

(72) Inventors: Ping-Wei Chang, San Jose, CA (US); Akira Okutomi, Saitama (JP); Bausan Yuan, San Jose, CA (US); Henry Kwok Pang Chau, Cupertino, CA (US)

(73) Assignee: NIKON CORPORATION, Tokyo (JP)

(21) Appl. No.: 13/738,666

(22) Filed: Jan. 10, 2013

Related U.S. Application Data
(60) Provisional application No. 61/585,953, filed on Jan. 12, 2012.

(51) Int. Cl. G03F 7/20

(52) U.S. Cl. CPC G03F 7/70725
USPC 355/72; 355/77

(57) ABSTRACT

A stage assembly (10) for positioning a device (22) along a first axis includes (i) a stage (14) that retains the device (22); (ii) a mover assembly (16) that moves the stage (14) along the first axis; (iii) an interferometer (26), (iv) an encoder (28), and (v) a control system (20). The interferometer (26) monitors the movement of the stage (14) along the first axis, the interferometer (26) generating an interferometer signal that relates to the movement of the stage (14) along the first axis. The encoder (28) monitors the movement of the stage (14) along the first axis, the encoder (28) generating an encoder signal that relates to the movement of the stage (14) along the first axis. The control system (20) utilizes both the encoder signal and the interferometer signal to control the mover assembly (16).

### RELATED APPLICATION

The application claims priority on U.S. Provisional Application Ser. No. 61/585,953 filed on Jan. 12, 2012, entitled “MEASUREMENT SYSTEM THAT INCLUDES AN ENCODER AND AN INTERFEROMETER”. As far as is permitted, the contents of U.S. Provisional Application Ser. No. 61/585,953 are incorporated herein by reference.

### BACKGROUND

Exposure apparatuses are commonly used to transfer images from a reticle onto a semiconductor wafer during semiconductor processing. A typical exposure apparatus includes an illumination source, a reticle stage assembly that retains and positions a reticle, a lens assembly, a wafer stage assembly that retains and positions a semiconductor wafer, and a measurement system that monitors the position of the reticle and the wafer. The size of the images and the features within the images transferred onto the wafer from the reticle are extremely small. Accordingly, the precise relative positioning of the wafer and the reticle is critical to the manufacturing of high density, semiconductor wafers.

The accuracy of the positioning of the reticle and the wafer are directly tied to the accuracy of the measurement system. Unfortunately, existing measurement systems are not entirely satisfactory.

### SUMMARY

The present invention is directed to stage assembly for positioning a device along a first axis. In one embodiment, the stage assembly includes (i) a stage that is adapted to retain the device; (ii) a mover assembly that moves the stage along the first axis; (iii) an interferometer that monitors the movement of the stage along the first axis, the interferometer generating an interferometer signal that relates to the movement of the stage along the first axis; (iv) an encoder that monitors the movement of the stage along the first axis, the encoder generating an encoder signal that relates to the movement of the stage along the first axis; and (v) a control system that utilizes both the encoder signal and the interferometer signal in the control of the mover assembly to move the stage along the first axis.

The accuracy of the positioning of the stage is directly tied to the accuracy of the device used to measure the position of the stage. Thus, in certain embodiments, the present invention concurrently utilizes both the encoder and the interferometer to improve the measurement signal.

In one embodiment, the control system utilizes the interferometer signal to determine a non-linearity offset in encoder signal during operation of the stage assembly. Subsequently, the control system can utilize the encoder signal corrected with the non-linearity offset to control the mover assembly. Stated in another fashion, the control system can utilize the interferometer signal to calibrate the encoder signal, and the control system can utilize the calibrated encoder signal to control the stage mover assembly. Alternatively, for an exposure apparatus that also includes a reticle stage assembly, the control system can utilize the non-linearity offset to adjust the position of the reticle stage assembly.

As used herein, the phase “non-linearity offset” shall mean the discrepancy of encoder measurement system readout and actual position the encoder is detecting. This discrepancy can be attributed to the manufacturing limitation of encoder grating plate and the error sensitivity of grating plate's proximity to encoder read-heads, which when taken together would result in small but complex error distribution that does not appear “linear” or “simple”, hence the term “non-linearity offset”.

In certain embodiments, the control system includes computational software that separates a time domain fluctuation of the interferometer signal and extracts a non-linearity offset in encoder signal during operation of the stage assembly. Stated in another fashion, the control system removes the fluctuation of interferometer signal to create a processed interferometer signal that is used as a reference to determine a non-linearity offset for the encoder signal. With this design, the control system can use the interferometer signal to provide real time, in-situ, linearity correction to the encoder signals.

In another embodiment, the stage assembly includes (i) a stage; (ii) a mover assembly that moves the stage; (iii) an interferometer that monitors the movement of the stage along the first axis, (iv) an encoder that monitors the movement of the stage along the first axis, and (v) a control system that controls the mover assembly to move the stage along the first axis, the control system utilizing the interferometer signal to determine a non-linearity offset in the encoder signal.

In still another embodiment, the present invention is directed to a method that includes the steps of: (i) retaining the device with a stage; (ii) moving the stage along the first axis with a mover assembly; (iii) monitoring the movement of the stage along the first axis with an interferometer that generates an interferometer signal that relates to the movement of the stage along the first axis; (iv) monitoring the movement of the stage along the first axis with an encoder that generates an encoder signal that relates to the movement of the stage along the first axis; and (v) controlling the mover assembly with a control system, the control system utilizing the interferometer signal to determine a non-linearity offset in the encoder signal.

The present invention is also directed to a stage assembly, an exposure apparatus, a device manufactured with the exposure apparatus, and/or a wafer on which an image has been formed by the exposure apparatus. Further, the present invention is also directed to a method for moving a stage, a method for making a stage assembly, a method for making an exposure apparatus, a method for making a device and a method for manufacturing a wafer.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a simplified perspective view of a stage assembly having features of the present invention;

FIG. 2A is a simplified top view of a portion of the stage assembly illustrating an encoder coordinate system established by an encoder;

FIG. 2B is a simplified top view of a portion of the stage assembly illustrating an interferometer coordinate system established by an interferometer;

FIG. 2C is a simplified top view of a portion of the stage assembly illustrating a calibrated encoder coordinate system;

FIG. 3 is a simplified schematic of a filter having features of the present invention;

FIG. 4 is a graph that illustrates actual image results without use of the present invention, and a non-linearity of the encoder;

FIG. 5 is a schematic illustration of an exposure apparatus having features of the present invention;

FIG. 6A is a flow chart that outlines a process for manufacturing a device in accordance with the present invention; and

FIG. 6B is a flow chart that outlines device processing in more detail.

### DESCRIPTION

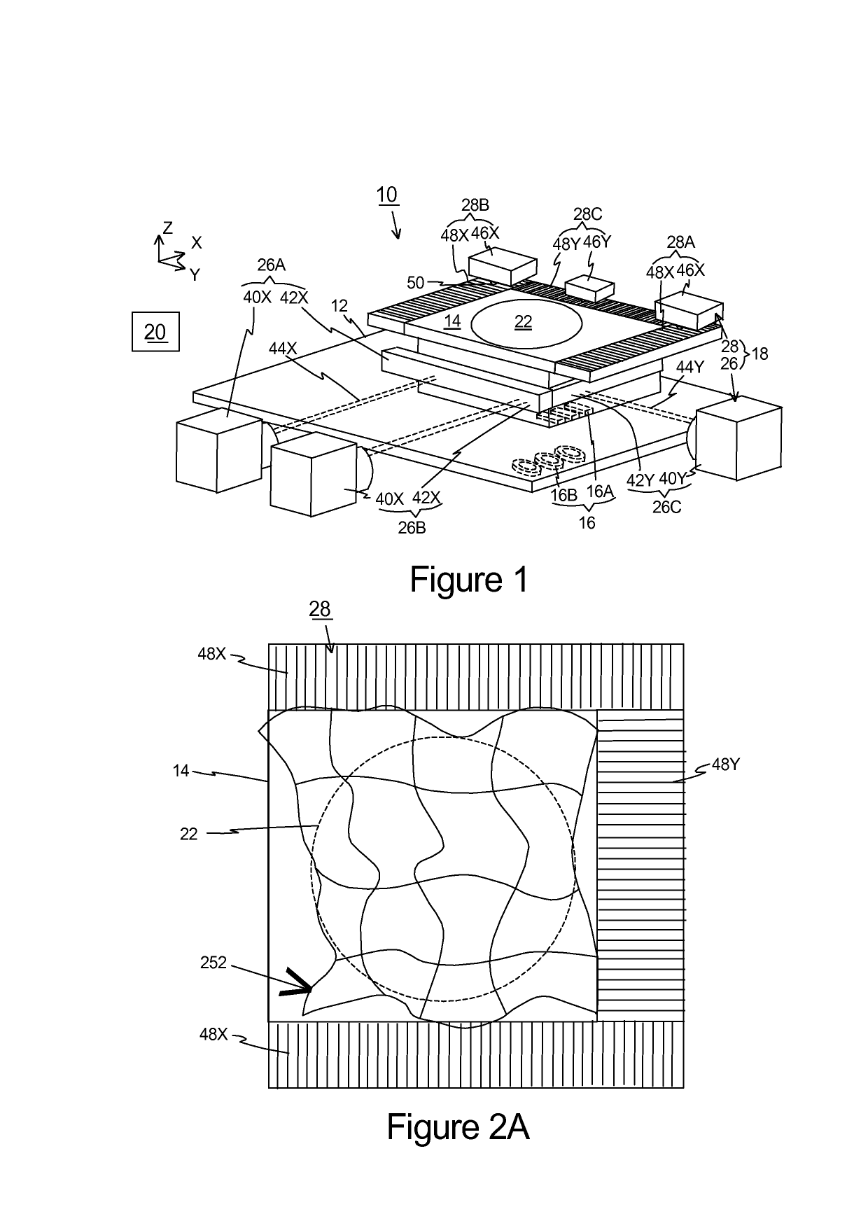

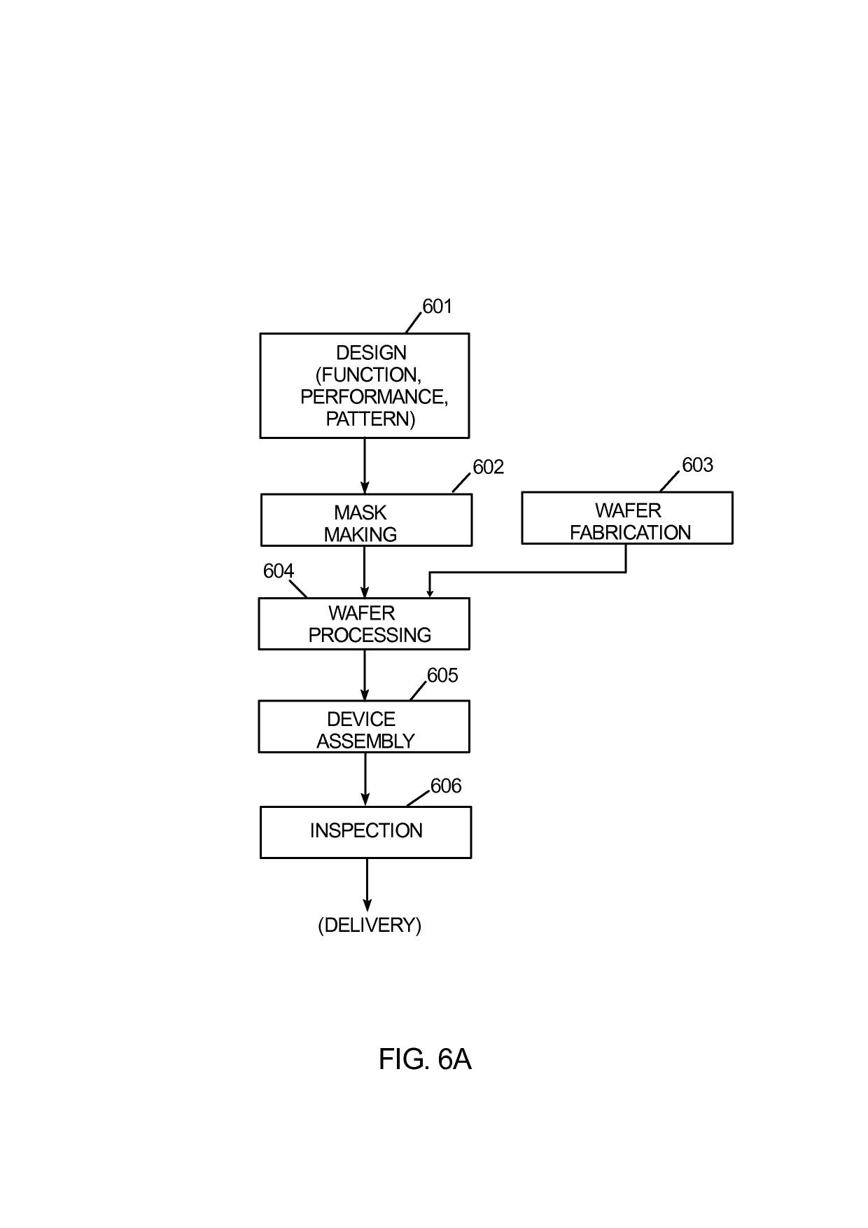

FIG. 1 is a simplified illustration of a stage assembly 10 that includes a stage base 12, a stage 14, a stage mover assembly 16 (illustrated in phantom), a measurement system 18, and a control system 20 (illustrated as a box). The design of each of these components can be varied to suit the design requirements of the stage assembly 10. The stage assembly 10 is particularly useful for precisely positioning a device 22 during a manufacturing and/or an inspection process. The type of device 22 positioned and moved by the stage assembly 10 can be varied. For example, the device 22 can be a semiconductor wafer, or a reticle, and the stage assembly 10 can be used as part of an exposure apparatus 524 (illustrated in FIG. 5) for precisely positioning the wafer or the reticle during manufacturing of the semiconductor wafer. Alternately, for example, the stage assembly 10 can be used to move other types of devices during manufacturing and/or inspection, to move a device under an electron microscope (not shown), or to move a device during a precision measurement operation (not shown).

As an overview, in certain embodiments, the measurement system 18 utilizes both an interferometer system 26 and an encoder system 28 to monitor the movement and/or position of the stage 14 along at least one axis. Further, in certain embodiments, the control system 20 utilizes both the interferometer signals from the interferometer system 26 and the encoder signals from the encoder system 28 to control the stage mover assembly 16. For example, the control system 20 can utilize a computational method that separates a time domain fluctuation of the interferometer system 26 and extracts a non-linearity offset in the encoder system 28 to generate an improved measurement signal.

Some of the Figures provided herein include an orientation system that designates an X axis, a Y axis, and a Z axis. It should be understood that the orientation system is merely for reference and can be varied. For example, the X axis can be switched with the Y axis and/or the stage assembly 10 can be rotated. Moreover, these axes can alternatively be referred to as a first, second, or third axis.

In the embodiments illustrated herein, the stage assembly 10 includes a single stage 14 that retains the device 22. Alternately, for example, the stage assembly 10 can be designed to include multiple stages that are independently moved and monitored with the measurement system 18.

The stage base 12 supports a portion of the stage assembly 10 above a mounting base 530 (illustrated in FIG. 5). In the non-exclusive example illustrated in FIG. 1, the stage base 12 is generally rectangular plate shaped.

The stage 14 retains the device 22. In one embodiment, the stage 14 is precisely moved by the stage mover assembly 16 to precisely position the stage 14 and the device 22. In FIG. 1, the stage 14 is generally rectangular shaped and includes a device holder (not shown) for retaining the device 22. The device holder can be a vacuum chuck, an electrostatic chuck, or some other type of clamp.

The stage mover assembly 16 moves and positions of the stage 14 relative to the stage base 12. The design of the stage mover assembly 16 can be varied to suit the movement requirements of the stage assembly 10. For example, the stage mover assembly 16 can be designed to move the stage 14 along the X axis, along the Y axis, and about the Z axis (collectively “the planar degrees of freedom”) relative to the stage base 12. In this embodiment, a fluid bearing or another type of bearing (e.g. a magnetic bearing) can support the stage 14 above the stage base 12 while allowing for movement of the stage 14 relative to the stage base 12 in the planar degrees of freedom.

Alternatively, the stage mover assembly 16 can be designed to move the stage 14 with more than three or fewer than three degrees of freedom. For example, the stage mover assembly 16 can be designed to move the stage 14 with six degrees of freedom relative to the stage base 12. In yet another example, the stage mover assembly 16 can be designed to move the stage 14 along a single axis, e.g. along the X axis.

In one embodiment, the stage mover assembly 16 is a planar motor that includes a plurality of moving components 16A (a few are illustrated in phantom) that are secured to the stage 14 and a plurality of reaction components 16B (a few are illustrated in phantom) that are secured to the stage base 12. For example, the moving components 16A can be magnets, and the reaction components 16B can be conductors. With this design, current can be directed to the conductors to selectively move the stage 14.

Alternatively or additionally, the stage mover assembly 16 can include one or more linear actuators, one or more voice coil motors, one or more attraction only actuators, and/or another type of actuator.

In yet another alternative embodiment, the reaction components 16B of the stage mover assembly 16 can be secured to a reaction mass (not shown) or a reaction frame (not shown) that inhibits the transfer of reaction forces to the stage base 12.

The measurement system 18 monitors the movement and/or the position of the stage 14 relative to a reference, such as an optical assembly 534 (illustrated in FIG. 5) or the stage base 12. With this information, the stage mover assembly 16 can be controlled by the control system 20 to precisely position the stage 14.

As provided herein, in certain embodiments, the measurement system 18 utilizes (i) the encoder system 28 that monitors the movement of the stage 14, and (ii) an interferometer system 26 that also monitors the movement of the stage 14. The design of the measurement system 18 can be varied according to the movement requirements of the stage 14.

In the non-exclusive embodiment illustrated in FIG. 1, the stage mover assembly 16 moves the stage 14 along the X axis, along the Y axis, and about the Z axis. In this embodiment, (i) the encoder system 28 monitors the movement of the stage 14 along the X axis, along the Y axis, and about the Z axis, and (ii) the interferometer system 26 monitors the movement of the stage 14 along the X axis, along the Y axis, and about the Z axis. In this embodiment, (i) the encoder system 28 includes three encoders 28A, 28B, 28C that each monitor the movement of the stage 14, and (ii) the interferometer system 26 includes three interferometers 26A, 26B, 26C that each monitor the movement of the stage 14.

More specifically, in FIG. 1, the encoder system 28 includes (i) a first X encoder 28A that provides a first X encoder signal that relates to the movement of the stage 14 along the X axis; (ii) a second X encoder 28B that provides a second X encoder signal that relates to the movement of the stage 14 along the X axis; and (iii) a Y encoder 28C that provides a Y encoder signal that relates to the movement of the stage 14 along the Y axis. It should be noted that the difference between the X encoder signals can be used to monitor the movement of the stage 14 about the Z axis. Further, in FIG. 1, the interferometer system 26 includes (i) a first X interferometer 26A that provides a first X interferometer signal that relates to the movement of the stage 14 along the X axis; (ii) a second X interferometer 26B that provides a second X interferometer signal that relates to the movement of the stage 14 along the X axis; and (iii) a Y interferometer 26C that provides a Y interferometer signal that relates to the movement of the stage 14 along the Y axis. Somewhat similarly, the difference between the X interferometer signals can be used to monitor the movement of the stage 14 about the Z axis.

Alternatively, the measurement system 18 can include additional encoders (not shown) and/or additional interferometers (not shown) to monitor other degrees of movement. Still alternatively, one or more encoders can be used design to monitor movement along more than one axis

In yet another alternative example, for a stage 14 that is moved along a single axis (e.g. the X axis), the measurement system 18 can include (i) a single encoder 28A that monitors the movement of the stage 14 along the X axis and that provides an encoder signal that relates to the movement along the X axis; and (ii) a single interferometer 26A that monitors the movement of the stage 14 along the X axis and that provides an interferometer signal that relates to the movement along the X axis.

The design of the interferometers 26A, 26C, 26C can be varied. In FIG. 1, (i) each X interferometer 26A, 26B includes a separate X beam source/receiver 40X and a X common mirror 42X; and (ii) the Y interferometer 26C includes a Y beam source/receiver 40Y and a Y mirror 42Y. Each X beam source/receiver 40X directs an X interferometer beam 44X (illustrated with a dashed beam) at the X mirror 42X and receives the beam reflected off of the mirror 42X. Similarly, the Y beam source/receiver 40Y directs a Y interferometer beam 44Y (illustrated with a dashed beam) at the Y mirror 42Y and receives the beam reflected off of the mirror 42Y.

In FIG. 1, each mirror 42X, 42Y is attached to the stage 14 and the beam source/receiver 40X, 40Y can be attached to the reference (not shown in FIG. 1). Each interferometer 26A, 26B, 26C generates an interferometer signal that relates to the relative position between the beam source/receiver 40X, 40Y, and the respective mirror 42X, 42Y. Because, the mirrors 42X, 42Y are attached to the stage 14 and the beam source/receivers 40X, 40Y are attached to the reference, the interferometer signal also relates to the relative position of the stage 14 (and device 22) and the reference.

The design of the encoders 28A, 28B, 28C can also be varied. In FIG. 1, (i) each X encoder 28A, 28B includes an X encoder head 46X and an X encoder grating plate 48X; and (ii) the Y encoder 28C includes a Y encoder head 46Y and a Y encoder grating plate 48Y. Each encoder head 46X, 46Y directs an encoder beam 50 (illustrated with a dashed beam) at the respective encoder grating plate 48X, 48Y. In FIG. 1, each encoder grating plate 48X, 48Y is attached to the stage 14 and each encoder head 46X, 46Y can be attached to the reference (not shown in FIG. 1). With this design, each encoder 28A, 28B, 28C generates an encoder signal that relates to the movement between the encoder grating plate 48X, 48Y and its corresponding encoder head 46X, 46Y. Because, the encoder grating plates 48X, 48Y are attached to the stage 14 and the encoder heads 46X, 46Y are attached to the reference, the encoder signal also relates to the movement of the stage 14 (and device 22) relative to the reference.

As provided herein, each encoder 28A, 28B, 28C has very good stability (repeatability), but is plagued by non-linearity. One cause of the non-linearity is the variations (during manufacturing) in spacing of the encoder lines on the encoder grating plates 48X, 48Y.

Further, as provided herein, each interferometer 26A, 26B, 26C has good linearity, but suffers from slow fluctuation in time domain. Typically, the interferometer beam 44X, 44Y travels through air (or other fluid) a relatively large distance between the source/receiver 40X, 40Y and the mirror 42X, 42Y. For example, over time, environmental factors such as the pressure, temperature, and/or humidity of the air will change. This will cause the interferometer signal to drift.

In contrast, the encoder beam 50 travels a relatively short distance, and is less influenced by the environmental changes in the air.

The accuracy of the positioning of the stage 14 (and the accuracy and overlay performance of an exposure apparatus 524) are directly tied to the accuracy of the measurement system 18. Thus, in certain embodiments, the present invention concurrently utilizes both the encoder system 28 and the interferometer system 26 to improve the measurement signal.

The control system 20 is electrically connected to the measurement system 18, and utilizes the encoder signals and the interferometer signals to monitor the movement of the stage 14. The control system 20 is also electrically connected to, directs and controls electrical current to the stage mover assembly 16 to precisely position the device 22. With information regarding the movement of the stage 14, the control system 20 can direct current to the stage mover assembly 16 so that the stage 14 follows the desired trajectory. The control system 20 can include one or more processors.

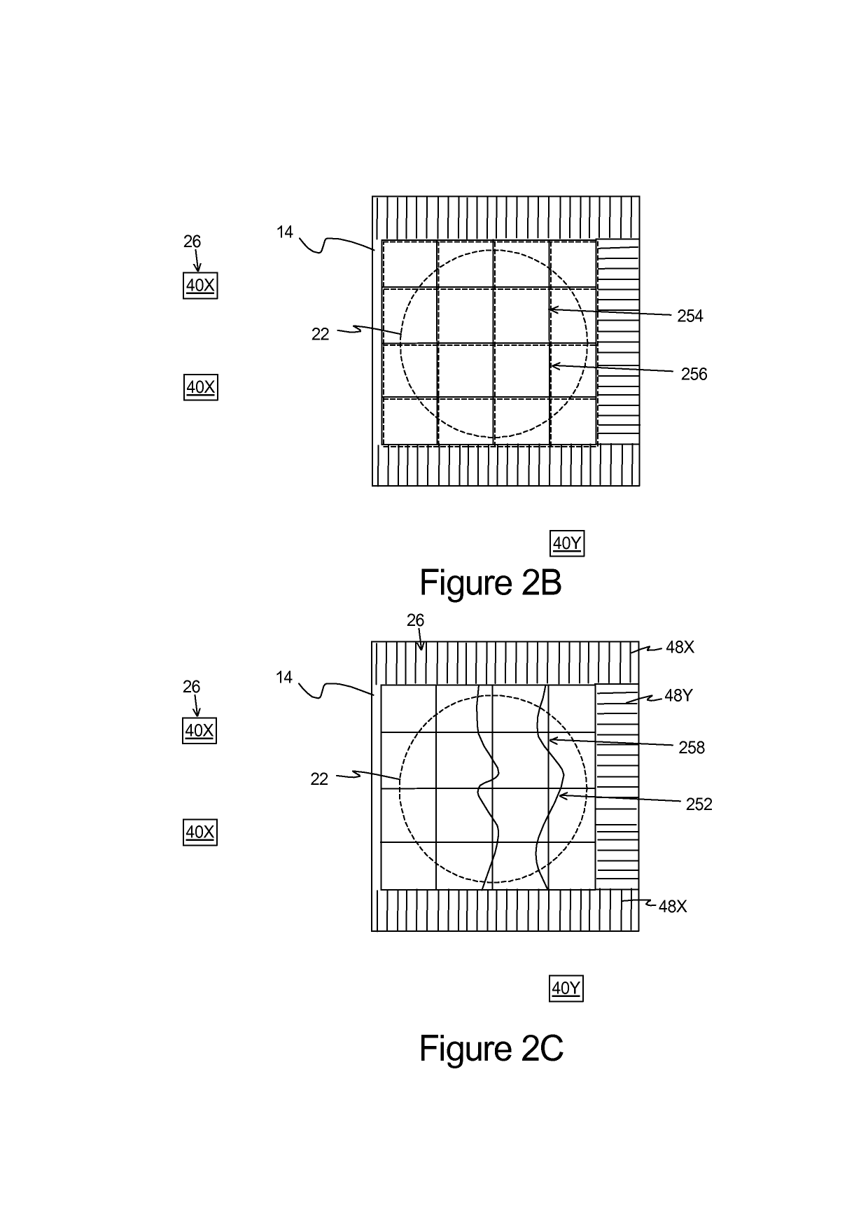

As mention above, the encoders 28A, 28B, 28C have very good stability (repeatability), but are plagued by non-linearity. FIG. 2A is a simplified top view of the stage 14, the device 22 (illustrated with dashed lines), the encoder grating plates 48X, 48Y and an encoder coordinate system 252 established utilizing the encoder system 28. In this example, the encoder system 28 was providing encoder signals to the control system 20 (illustrated in FIG. 1), and the control system 20 is trying to control the stage mover assembly 16 (illustrated in FIG. 1) to move the stage 14 to follow a two dimensional, rectangular grid type pattern with straight lines. However, because of the non-linearity of the encoders 28A, 28B, 28C, the lines of the encoder coordinate system 252 illustrated in FIG. 2A are curved physically (and observable with an interferometer), even though the stage assembly 10 is attempting to move the stage 14 to follow straight lines. It should be noted that the curves are greatly exaggerated for clarity in FIG. 2A.

In contrast, FIG. 2B is a simplified top view of the stage 14, the device 22 (dashed lines), the source/receivers 40X, 40Y of the interferometer system 26, and a first interferometer coordinate system 254 established utilizing the interferometer system 26 at a first time. In this example, the interferometer 26 was providing interferometer signals to the control system 20 (illustrated in FIG. 1), and the control system 20 was controlling the stage mover assembly 16 (illustrated in FIG. 1) to move the stage 14 to follow a two dimensional, rectangular grid type pattern with straight lines. Because of the good linearity of the interferometer system 26, the lines of the first interferometer coordinate system 254 illustrated in FIG. 2B are straight.

However, the interferometer 26 suffers from slow fluctuation in the time domain. Thus, FIG. 2B includes a dashed, second interferometer coordinate system 256 established utilizing the interferometer system 26 at a second time. The second interferometer coordinate system 256 has good linearity, but is offset from the first interferometer coordinate system 254 because of the fluctuation in time domain.

Referring back to FIG. 1, in one embodiment, the control system 20 utilizes the interferometer signals from the interferometer system 26 as a reference to calibrate the encoder system 28. Further, the control system 20 uses the encoder signals from the encoder system 28 to control the stage mover assembly 16 to position the stage 14. For example, the interferometer signals can be used to learn where the true straight lines of the encoder coordinate system 252 (illustrated in FIG. 2A) are. Stated in another fashion, the interferometer signals can be used to control the stage mover assembly 16 to move the stage 14 along the straight lines of the first interferometer coordinate system 254 (illustrated in FIG. 2B) while monitoring the corresponding (“calibrated”) encoder signals to learn which encoder signals result in the straight lines of the first interferometer coordinate system 54. Subsequently, the calibrated encoder can be used by the control system to control the stage mover assembly 16 in a repeatable fashion.

FIG. 2C is a simplified top view of the stage 14, the device 22 (dashed), the source/receiver heads 40X, 40Y of the interferometer system 26, the encoder plates 48X, 48Y of the encoder system 28, and a calibrated encoder coordinate system 258 established utilizing both the encoder system 28 and the interferometer 26. In this example, the control system 20 has learned (with reference to the interferometer signals) the encoder signals that will result in the stage mover assembly 16 moving the stage 14 to follow a rectangular grid type encoder coordinate system 258. Because of the calibration of the encoder 28, the lines of the calibrated encoder coordinate system 258 illustrated in FIG. 2C are straight and are no longer curved. It should be noted that a portion of the original encoder coordinate system 252 is illustrated in FIG. 2C for reference.

Subsequently, in certain embodiments, after the linearity (straightness) of the encoder coordinate system 258 has been learned, the control system 20 may no longer use interferometer signal and the interferometer system 26 can be turned off.

Alternatively, for example, with reference to FIG. 5, if the stage assembly is a wafer stage assembly 510 for an exposure apparatus 524, once the waviness of the original encoder coordinate system 252 (illustrated in FIG. 2A) is learned utilizing the interferometer system 26, instead of correcting the path followed by the wafer 522, the control system 520 can control and adjust the path of a reticle 562 to compensate for the irregular, curved path followed by the wafer 522.

Referring back to FIG. 1, in yet another embodiment, the control system 20 will continue to utilize both the encoder system 28 and the interferometer system 26 to monitor the movement of the stage 14 during the operation of the stage assembly 10 (e.g. during exposure of a wafer).

As provided herein, in certain embodiments, the stage assembly 10 will be used to sequentially move and position a number of very similar, but slightly different devices 22. For example, if the stage assembly 10 is used to position wafers 522 during a lithography process, each wafer 522 will be similar, but because of manufacturing tolerances, each wafer 522 will be slightly different. As a result thereof, the location of where the images are to be transferred will vary from wafer 522 to wafer 522. Stated in another fashion, because each wafer 522 is slightly different, (i) each wafer 522 will need to travel through a slightly different path than the calibrated encoder path 258, and/or (ii) the path of the reticle will have to be adjusted to compensate for the differences in the wafer 522. Thus, the original calibration of the encoder signal does not cover all possible situations.

As a result thereof, in certain embodiments, after the linearity (straightness) of the encoder coordinate system 258 has been learned, the control system 20 still uses the interferometer signal from the interferometer system 26 (in addition to the encoder signal of the encoder system 28) during movement of the stage 14. In one embodiment, the control system 20 utilizes a computational method (software) that separates the time domain fluctuation of the interferometer system 26 and extracts the new non-linearity offset in encoder system 28 for each subsequent wafer 522 due to stage 14 trajectory variation during normal operation of the stage assembly 10. As provided herein, the software can be embedded with an algorithm that infers the true linearity of the interferometer system 26 with not only the existing calibration history but also the real-time interferometer measurements. The algorithm can extract the real time linearity of the interferometer system 26, while at the same time removing the fluctuation part of interferometer system 26 by reference to past history such as calibration data.

Stated in yet another fashion, in certain embodiments, the algorithm used by the control system 20 can utilize the interferometer signals to provide real time, in-situ, linearity correction to the encoder signals. More specifically, in one embodiment, the control system 20 removes the fluctuation of interferometer signals, and in turn, this processed interferometer signal serves as reference for the encoder system 28 to determine its true non-linearity for each subsequent wafer 522. The end result is a measurement system 18 that combines the respective advantage from both the interferometer system 26 and the encoder system 28, while removing the disadvantages of both the interferometer system 26 and the encoder system 28.

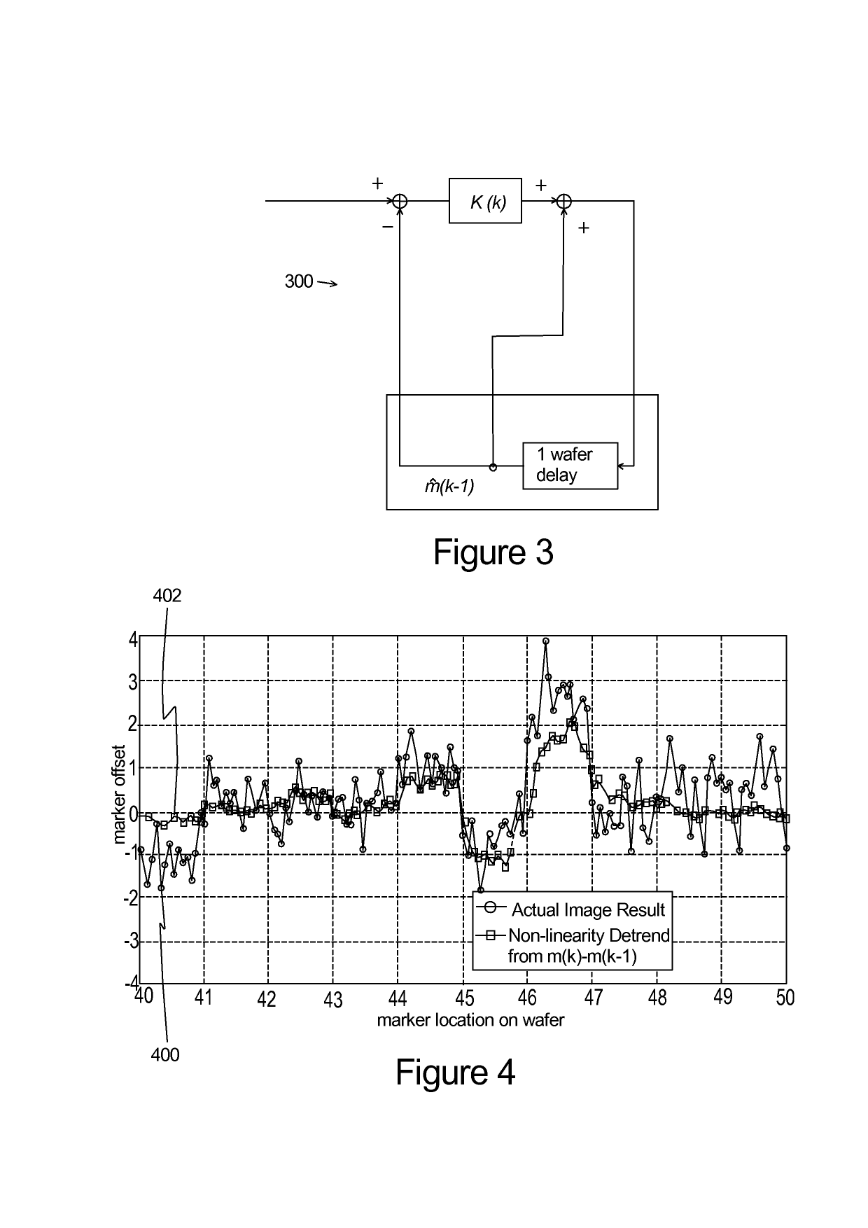

FIG. 3 is a simplified schematic of one non-exclusive example of a common filter 300 that can be used to filter out the fluctuations in the interferometer signal from the interferometers 26A, 26B, 26C (illustrated in FIG. 1). It should be noted that another type of filter can be used to filter out the fluctuations in the raw interferometer signal from the interferometers 26A, 26B, 26C. The following equations 1-6 assist in the explanation the filter 300. In these equations, (i) k is the wafer; (ii) m(k) is the raw non-linearity offset; (iii) IF is the interferometer signal; (iv) ENC is the raw encoder signal; (v) K is the gain of the filter; (vi) \hat{P}(k) is an internal variable (running statistics); (vii) \hat{Q}(k) is a statistical difference between the current wafer (k) as compared to subsequent wafers (k−1), (k−2); (viii) \hat{R}(k) is the standard deviation (the fluctuation level for all of the wafers); and (ix) \hat{m}(k) is the filtered output.

As provided herein, the raw “non-linearity offset” is calculated as follows:

m(k)=I\tilde{F}(k)−ENC(k) Equation 1

Thus, in this example, the raw “non-linearity offset” is equal the raw interferometer signal (designated as “I\tilde{F}(k)”) minus the encoder signal. I\tilde{F} is the raw measurement reading (subsequent to the filtering). Therefore m(k) is a “derived” or “computed” signal that is simply the difference between the raw interferometer signal and the raw encoder signal.

Further, the gain of the filter can be calculated as follows:

$$K ( k ) = \frac{\hat{P} ( k )}{\hat{P} ( k ) + \hat{R} ( k )} \qquad Equation 2$$

The internal variable can be calculated as follows:

\hat{P}(k)=\hat{P}(k−1)+\hat{Q}(k−1) Equation 3

The statistical difference can be calculated as follows:

\hat{Q}(k)=(\hat{m}(k−2)−\hat{m}(k=2))² Equation 4

The standard deviation can be calculated as follows;

\hat{R}(k)=σ²{m(k)=\hat{m}(k−1),m(k−1)−\hat{m}(k−2), . . . m(1)−\hat{m}(0)} Equation 5

Moreover, the filtered output can be calculated as follows:

\hat{m}(k)=\hat{m}(k−1)+K(k)[m(k)−\hat{m}(k−1)] Equation 6

Thus, equations 1-6 can be used to determine the filtered output.

It should be noted that the statistical difference \hat{Q}(k) can be calculated in other ways than provided in Equation 4. Other, non-exclusive ways to calculate the statistical difference \hat{Q}(k) include (i) the square sum of square of m(k) from initial wafer k=0 to

$$Q ( k ) = {\sum }_{t = 00}^{k} {( \hat{m} ( t ) - \hat{m} ( t - 1 ) )}^{2} ,$$

(where the statistical difference \hat{Q}(k) is refined by a lot of the data of the wafer); (ii) referring to the latest value only, Q(k)=(\hat{m}(t)−\hat{m}(t−1))²; or (iii) the range of integration [t0,k] change adaptively,

$$Q ( k ) = {\sum }_{t = {t}_{0}}^{k} {( \hat{m} ( t ) - \hat{m} ( t - 1 ) )}^{3} .$$

As provided herein, the control system 20 receives a raw interferometer signal (designated as “I\tilde{F}(k)”) from each interferometer 26A, 26B, 26C. For each interferometer 26A, 26B, 26C, the raw interferometer signal includes fluctuations caused by environmental changes. Taken by itself, the error fluctuation in interferometer is hard to detect because the small fluctuation is overwhelmed by the ever-changing measuring positions the interferometer I\tilde{F}(k) is tasked to scan. However since the encoder is simultaneously measuring the identical positions as the interferometer, their differences, described by Equation 7 (below) reveals a very clear signal wherein both ‘encoder non-linearity offset’ and ‘interferometer fluctuation’ are contained. As provided herein, the control system 20 utilizes the filter 300 to filter out the fluctuations in the raw interferometer signal for each interferometer 26A, 26B, 26C to obtain the filtered interferometer signal (designated as “IF(k)”) for each interferometer 26A, 26B, 26C, by the filtering algorithm described in Equations. 1-6.

The raw ‘non-linearity offset’ signal (raw in the sense it contains the interferometer fluctuation) is again represented in Equation 7 (similar to Equation 1):

m(k)=I\tilde{F}(k)−ENC(k) Equation 7.

The filtered encoder ‘non-linearity offset’ signal is thus obtained by the filter output \hat{m}(k) which can also be written as the difference between clean interferometer position (now free of interferometer fluctuation) and encoder position (whose non-linearity offset part is still preserved) by Equation 8:

\hat{m}(k)=IF(k)−ENC(k) Equation 8.

As provided above, all of the wafers are slightly different. Thus, wafer k is different from wafer k−1 (the previous wafer). Each wafer loading will induce new Encoder Non-Linearity. The following Equations 9-11 can be used to determine the new non-linearity of the encoder for each wafer.

$$\begin{matrix}{\hat{m}}_{1} ( k ) - {\hat{m}}_{1} ( k - 1 ) = \{ {IF}_{1} ( k ) - {IF}_{1} ( k - 1 ) \} - \{ {ENC}_{1} ( k ) - {ENC}_{1} ( k - 1 ) \} & Equation 9 \\ {\hat{m}}_{2} ( k ) - {\hat{m}}_{2} ( k - 1 ) = \{ {IF}_{2} ( k ) - {IF}_{2} ( k - 1 ) \} - \{ {ENC}_{2} ( k ) - {ENC}_{2} ( k - 1 ) \} \\ ⋮ & Equation 10 \\ {\hat{m}}_{n} ( k ) - {\hat{m}}_{n} ( k - 1 ) = \{ {IF}_{n} ( k ) - {IF}_{n} ( k - 1 ) \} - \{ {ENC}_{n} ( k ) - {ENC}_{n} ( k - 1 ) \} . & Equation 11\end{matrix}$$

The subscripts in equations 9-11 represent a different location (marker) on the respective wafers k and k−1. For example, (i) \hat{m}₁(k) represents the filtered output signal at location (marker) 1 on wafer k, (ii) \hat{m}₁(k−1) represents the filtered output signal at location (marker) 1 on wafer k−1; (iii) while \hat{m}₂(k) represents the filtered output signal at location (marker) 2 on wafer k; (iv) IF represents the interferometer signal for the location (marker) 1 on wafer k; and (v) ENCᵢ(k) represents the encoder signal for the location (marker) 1 on wafer k. Each wafer k, k−1 will have a plurality of corresponding markers that are used for aligning the respective wafer.

In Equations 9-11 describes a typical lithography operation, the subscript i in \hat{m}ᵢ represents a time ordered sequential events as i enumerates from 1 to n i=1,2, . . . , n; further the nature of slow fluctuation in interferometer ensures the wafer-to-wafer same-event(marker) discrepancy {IFᵢ(k)−IFᵢ(k−1)} be at most a simple offset or an event (i) ordered linear trend. On the other hand, during the same operation sequence (event/marker i=1,2, . . . n), the encoder part “{ENCᵢ(k)−ENCᵢ(k−1)}” contains the new information of encoder new non-linearity. Consequently if we examine the wafer-to-wafer filtered differences of ‘non-linearity offset’ \hat{m}ᵢ(k)−\hat{m}ᵢ(k−1) we can extract current wafer's change of non-linearity offset by simply taking out the linear trend of \hat{m}ᵢ(k)−\hat{m}ᵢ(k−1).

Further, in certain embodiments, the encoder signal is the main signal used to position the stage. In these embodiments, the goal is to obtain the new encoder signal non-linearity of each wafer, e.g. wafer k. As provided herein, in certain embodiments, the new encoder signal non-linearity of each wafer can be obtained by removing the linear trend of \hat{m}ᵢ(k)−\hat{m}ᵢ(k−1) from Equations 9-11.

Stated in another fashion, in certain embodiments, with the present invention, for each interferometer 26A, 26B, 26C, the difference between raw interferometer and encoder signals is first filtered for each of a plurality of alternative locations (markers). Subsequently, for each of the plurality of alternative locations, the filtered interferometer signal for the wafer k is compared to the corresponding filtered interferometer signal for the previous wafer k−1 or multiple previous wafers (represented by the {\hat{m}ᵢ(k)−\hat{m}ᵢ(k−1)} in Equations 9-11).

Next, the linear trend of the values of the difference between the filter signal of the wafer k and the filtered signal of the previous wafer k−1 (‘\hat{m}ᵢ(k)\hat{m}ᵢ(k−1)“) for the plurality of locations can be used to obtain the encoder non-linearity for the wafer k.

For an exposure apparatus 524, with information regarding the new encoder signal non-linearity for wafer k, the control system 20 (i) can control the mover assembly to position the wafer k 522 with improved accuracy utilizing the encoder (straightened out, calibrated encoder coordinate system 258) so that the image is transferred to correct place on wafer k, and/or (ii) can control the mover assembly to adjust the path/position of the reticle to compensate for the incorrect curved path/positioning of the wafer k so that the image is transferred to the correct place on the wafer k.

The process of determining the encoder non-linearity can be performed on each wafer.

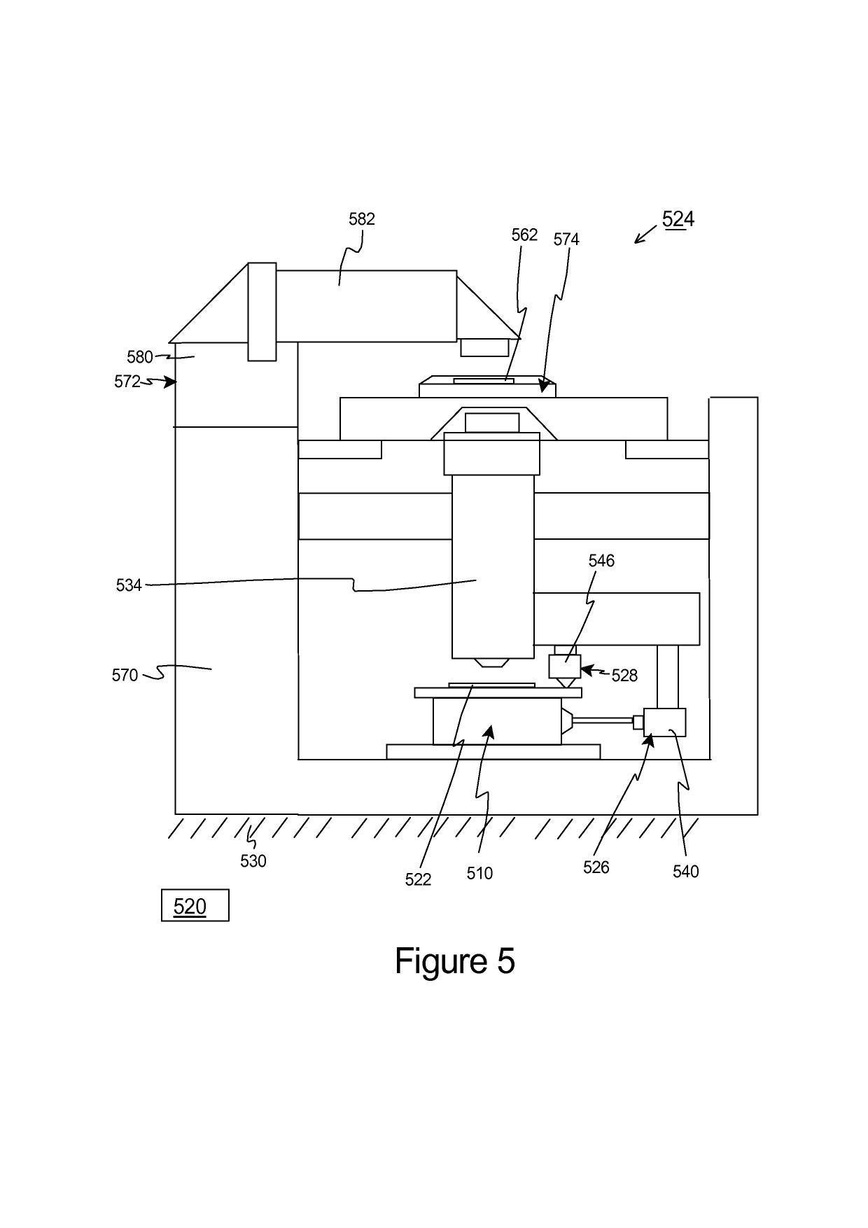

FIG. 4 is a graph that plots marker offset versus marker location on the wafer. This graph includes a first line 400 (solid line with circles) that plots the actual image (exposure) results without use of the present invention that was measured. Any value other than zero is misplaced by the amount different than zero. For example, (i) the image transferred to marker address (location) slightly greater than 40 is off approximately −1; and (ii) the image transferred to marker address (location) 44 is off approximately greater than 1.

FIG. 4 also includes a second line 402 (solid line with squares) that plots a non-linearity detrend of one of the encoders. This line represents the calculated non-linearity of the one encoder for this wafer.

It should be noted that the non-linearity of the encoder matches the errors in the actual image misplacement. Thus, the encoder non-linearity can be utilized to reduce the actual image misplacement by positioning the wafer with improved accuracy and/or positioning the reticle to compensate for the inaccuracy of the positioning of the wafer.

FIG. 5 is a schematic view illustrating an exposure apparatus 524 useful with the present invention. The exposure apparatus 524 includes the apparatus frame 570, an illumination system 572 (irradiation apparatus), a reticle stage assembly 574, an optical assembly 534 (lens assembly), a wafer stage assembly 510, and a control system 520 that controls the reticle stage assembly 574 and the wafer stage assembly 510. The stage assemblies 10 illustrated in FIG. 1, can be used as the wafer stage assembly 510. Alternately, with the disclosure provided herein, the stage assembly 10 provided herein can be modified for use as the reticle stage assembly 574.

The exposure apparatus 524 is particularly useful as a lithographic device that transfers a pattern (not shown) of an integrated circuit from the reticle 562 onto the semiconductor wafer 522. The exposure apparatus 524 mounts to the mounting base 530, e.g., the ground, a base, or floor or some other supporting structure.

The apparatus frame 570 is rigid and supports the components of the exposure apparatus 524. The design of the apparatus frame 570 can be varied to suit the design requirements for the rest of the exposure apparatus 524.

The illumination system 572 includes an illumination source 580 and an illumination optical assembly 582. The illumination source 580 emits a beam (irradiation) of light energy. The illumination optical assembly 582 guides the beam of light energy from the illumination source 580 to the reticle 562. The beam illuminates selectively different portions of the reticle 562 and exposes the semiconductor wafer 522.

The optical assembly 534 projects and/or focuses the light passing through the reticle 562 to the wafer 522. Depending upon the design of the exposure apparatus 524, the optical assembly 534 can magnify or reduce the image illuminated on the reticle 562.

The reticle stage assembly 574 holds and positions the reticle 562 relative to the optical assembly 534 and the wafer 522. Similarly, the wafer stage assembly 510 holds and positions the wafer 522 with respect to the projected image of the illuminated portions of the reticle 562.

There are a number of different types of lithographic devices. For example, the exposure apparatus 524 can be used as scanning type photolithography system that exposes the pattern from the reticle 562 onto the wafer 522 with the reticle 562 and the wafer 522 moving synchronously. Alternatively, the exposure apparatus 524 can be a step-and-repeat type photolithography system that exposes the reticle 562 while the reticle 562 and the wafer 522 are stationary.

However, the use of the exposure apparatus 524 and the stage assemblies provided herein are not limited to a photolithography system for semiconductor manufacturing. The exposure apparatus 524, for example, can be used as an LCD photolithography system that exposes a liquid crystal display device pattern onto a rectangular glass plate or a photolithography system for manufacturing a thin film magnetic head. Further, the present invention can also be applied to a proximity photolithography system that exposes a mask pattern by closely locating a mask and a substrate without the use of a lens assembly. Additionally, the present invention provided herein can be used in other devices, including other semiconductor processing equipment, elevators, machine tools, metal cutting machines, inspection machines and disk drives.

In FIG. 5, the encoder head 546 of one encoder 528 and the source/receiver 540 of one of the interferometers 526 are secured to the optical assembly 534. As a result thereof, the measurements are referenced to the optical assembly 534.

Further, in certain embodiments, the optical assembly 534 is isolated from vibration and noise free. As a result thereof, the measurement systems are isolated from vibration.

As provided herein, the non-linearity of the encoder 528 can be determined utilizing the interferometer 526. The non-linearity of the encoder 528 can be utilized to in the control of the wafer stage assembly 610 to position the wafer 522 with improved accuracy. Alternatively, the non-linearity of the encoder 528 can be used by the control system to control the reticle stage assembly 574 to position the reticle 562 in a fashion that compensates for the inaccuracy of the positioning of the wafer 522.

A photolithography system according to the above described embodiments can be built by assembling various subsystems, including each element listed in the appended claims, in such a manner that prescribed mechanical accuracy, electrical accuracy, and optical accuracy are maintained. In order to maintain the various accuracies, prior to and following assembly, every optical system is adjusted to achieve its optical accuracy. Similarly, every mechanical system and every electrical system are adjusted to achieve their respective mechanical and electrical accuracies. The process of assembling each subsystem into a photolithography system includes mechanical interfaces, electrical circuit wiring connections and air pressure plumbing connections between each subsystem. Needless to say, there is also a process where each subsystem is assembled prior to assembling a photolithography system from the various subsystems. Once a photolithography system is assembled using the various subsystems, a total adjustment is performed to make sure that accuracy is maintained in the complete photolithography system. Additionally, it is desirable to manufacture an exposure system in a clean room where the temperature and cleanliness are controlled.

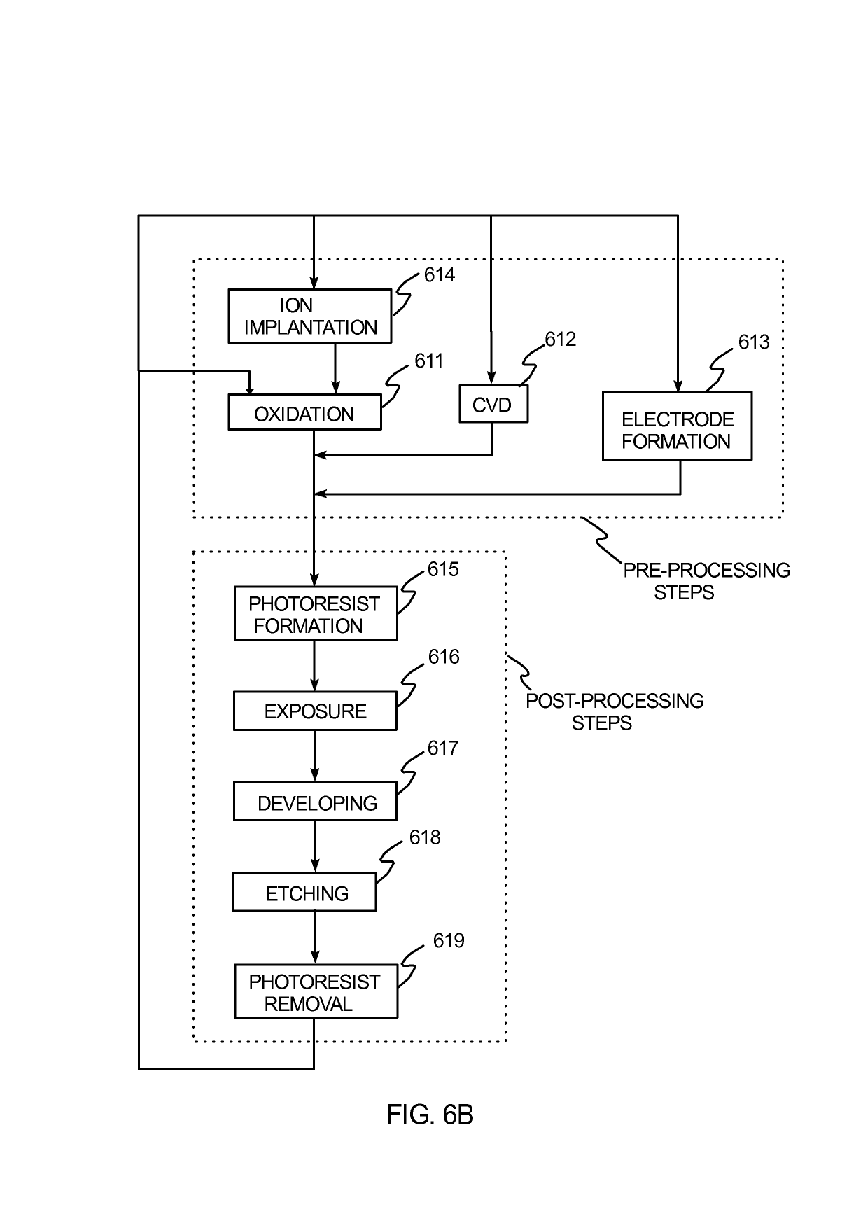

Further, semiconductor devices can be fabricated using the above described systems, by the process shown generally in FIG. 6A. In step 601 the device's function and performance characteristics are designed. Next, in step 602, a mask (reticle) having a pattern is designed according to the previous designing step, and in a parallel step 603 a wafer is made from a silicon material. The mask pattern designed in step 602 is exposed onto the wafer from step 603 in step 604 by a photolithography system described hereinabove in accordance with the present invention. In step 605 the semiconductor device is assembled (including the dicing process, bonding process and packaging process), finally, the device is then inspected in step 606.

FIG. 6B illustrates a detailed flowchart example of the above-mentioned step 604 in the case of fabricating semiconductor devices. In FIG. 6B, in step 611 (oxidation step), the wafer surface is oxidized. In step 612 (CVD step), an insulation film is formed on the wafer surface. In step 613 (electrode formation step), electrodes are formed on the wafer by vapor deposition. In step 614 (ion implantation step), ions are implanted in the wafer. The above mentioned steps 611-614 form the preprocessing steps for wafers during wafer processing, and selection is made at each step according to processing requirements.

At each stage of wafer processing, when the above-mentioned preprocessing steps have been completed, the following post-processing steps are implemented. During post-processing, first, in step 615 (photoresist formation step), photoresist is applied to a wafer. Next, in step 616 (exposure step), the above-mentioned exposure device is used to transfer the circuit pattern of a mask (reticle) to a wafer. Then in step 617 (developing step), the exposed wafer is developed, and in step 618 (etching step), parts other than residual photoresist (exposed material surface) are removed by etching. In step 619 (photoresist removal step), unnecessary photoresist remaining after etching is removed.

Multiple circuit patterns are formed by repetition of these preprocessing and post-processing steps.

While the particular stage assembly as shown and disclosed herein is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A stage assembly for positioning a device along a first axis, the stage assembly comprising:
a stage that is adapted to retain the device;
a mover assembly that moves the stage along the first axis;
an interferometer that monitors the movement of the stage along the first axis, the interferometer generating an interferometer signal that relates to the movement of the stage along the first axis;
an encoder that monitors the movement of the stage along the first axis, the encoder generating an encoder signal that relates to the movement of the stage along the first axis; and
a control system that utilizes both the encoder signal and the interferometer signal in the control of the mover assembly to move the stage along the first axis.

2. The stage assembly of claim 1 wherein the control system utilizes the interferometer signal to determine a non-linearity offset in encoder signal during operation of the stage assembly.

3. The stage assembly of claim 2 wherein the control system utilizes the encoder signal corrected with the non-linearity offset to control the mover assembly.

4. An exposure apparatus including an illumination source, a reticle stage assembly, and the stage assembly of claim 2 that moves the stage relative to the illumination system, wherein the control system utilizes the non-linearity offset to adjust the position of the reticle stage assembly.

5. The stage assembly of claim 1 wherein the control system utilizes the interferometer signal to calibrate the encoder signal, and the control system utilizes the calibrated encoder signal to control the stage mover assembly.

6. The stage assembly of claim 1 wherein the control system includes computational software that separates a time domain fluctuation of the interferometer signal and extracts a non-linearity offset in encoder signal during operation of the stage assembly.

7. The stage assembly of claim 1 wherein the control system uses the interferometer signal to provide real time, in-situ, linearity correction to the encoder signals.

8. The stage assembly of claim 1 wherein the control system removes the fluctuation of interferometer signal to create a processed interferometer signal that is used as reference to determine a non-linearity offset for the encoder signal.

9. An exposure apparatus including an illumination source, a reticle stage assembly, and the stage assembly of claim 1 that moves the stage relative to the illumination system.

10. A process for manufacturing a device that includes the steps of providing a substrate and forming an image to the substrate with the exposure apparatus of claim 9.

11. A stage assembly for positioning a device along a first axis, the stage assembly comprising:
a stage that is adapted to retain the device;
a mover assembly that moves the stage along the first axis;
an interferometer that monitors the movement of the stage along the first axis, the interferometer generating an interferometer signal that relates to the movement of the stage along the first axis;
an encoder that monitors the movement of the stage along the first axis, the encoder generating an encoder signal that relates to the movement of the stage along the first axis; and
a control system that controls the mover assembly to move the stage along the first axis, the control system utilizing the interferometer signal to determine a non-linearity offset in the encoder signal.

12. The stage assembly of claim 11 wherein the control system utilizes the encoder signal corrected with the non-linearity offset to control the mover assembly.

13. An exposure apparatus including an illumination source, a reticle stage assembly, and the stage assembly of claim 11 that moves the stage relative to the illumination system, wherein control system utilizes the non-linearity offset to adjust the position of the reticle stage assembly.

14. The stage assembly of claim 11 wherein the control system utilizes the interferometer signal to calibrate the encoder signal, and the control system utilizes the calibrated encoder signal to control the stage mover assembly.

15. The stage assembly of claim 11 wherein the control system includes computational software that separates a time domain fluctuation of the interferometer signal to generate a processed interferometer signal, and wherein the control system determines the non-linearity offset in encoder signal using the processed interferometer signal.

16. An exposure apparatus including an illumination source, a reticle stage assembly, and the stage assembly of claim 11 that moves the stage relative to the illumination system.

17. A process for manufacturing a device that includes the steps of providing a substrate and forming an image to the substrate with the exposure apparatus of claim 11.

18. A method for moving a device along a first axis, the method comprising the steps of:
retaining the device with a stage;
moving the stage along the first axis with a mover assembly;
monitoring the movement of the stage along the first axis with an interferometer that generates an interferometer signal that relates to the movement of the stage along the first axis;
monitoring the movement of the stage along the first axis with an encoder that generates an encoder signal that relates to the movement of the stage along the first axis; and
controlling the mover assembly with a control system, the control system utilizing the interferometer signal to determine a non-linearity offset in the encoder signal.

19. The method of claim 18 wherein the step of controlling includes the step of utilizing the encoder signal corrected with the non-linearity offset to control the mover assembly.

20. The method of claim 18 wherein the step of controlling includes the steps of utilizing the interferometer signal to calibrate the encoder signal, and utilizing the calibrated encoder signal to control the stage mover assembly.

21. The method of claim 18 wherein the step of controlling includes the steps of utilizing computational software to separates a time domain fluctuation of the interferometer signal to generate a processed interferometer signal, and utilizing the processed interferometer signal to determine the non-linearity offset in encoder signal.

22. A method for transferring an image to a device, the method comprising the steps of: (i) moving the device by the method of claim 18, and (ii) moving a reticle with a reticle stage assembly that is controlled by the control system; wherein the control system utilizes the non-linearity offset to adjust the position of the reticle stage assembly.

23. A stage assembly for positioning a device along a first axis, the stage assembly comprising:
a stage that is adapted to retain the device;
a mover assembly that moves the stage along the first axis;
a first monitor device that monitors the movement of the stage along the first axis, the first monitor device generating a first signal that relates to the movement of the stage along the first axis;
a second monitor device that monitors the movement of the stage along the first axis, the second monitor device generating a second signal that relates to the movement of the stage along the first axis; and
a control system that utilizes both the first signal and the second signal in the control of the mover assembly to move the stage along the first axis.

24. The stage assembly of claim 23 wherein the control system utilizes the first signal to determine a non-linearity offset in the second signal during operation of the stage assembly.
